(19) United States
(12) Patent Application Publication
(10) Pub. No.: US 2026/0215046 A1
(43) Pub. Date: Jul. 23, 2026

(54) MICRO-LED STRUCTURE FOR IMPROVING LIGHT EXTRACTION EFFICIENCY

(71) Applicant: Hue Inc., Shanghai (CN)

(72) Inventors: Anle Fang, Shanghai (CN); Weisin Tan, Shanghai (CN); Chenggen Wang, Shanghai (CN)

(73) Assignee: Hue Inc., Shanghai (CN)

(21) Appl. No.: 19/454,413

(22) Filed: Jan. 21, 2026

(30) Foreign Application Priority Data
Jan. 21, 2025 (CN) 202510092495.3

(51) Int. Cl. H10H 20/856; H10H 20/812; H10H 20/831; H10H 20/833; H10H 20/84; H10H 29/39

(52) U.S. Cl. CPC H10H 20/856; H10H 20/812; H10H 20/831; H10H 20/833; H10H 20/84; H10H 29/39

(57) ABSTRACT

The present invention provides a micro-LED structure, including: a lower electrode layer; an ODR total reflection structure located on the lower electrode layer; a semiconductor light-emitting mesa located on the ODR total reflection structure, emitting light; and an upper electrode layer in contact with the top of the semiconductor light-emitting mesa. The micro-LED increases the probability of light leaving the light-emitting mesa by increasing the sidewall light emission area of the micro-LED structure, thereby improving the light emission efficiency of the LED chip.

### CROSS-REFERENCE TO RELATED APPLICATION

This application claims the priority benefit of Chinese patent application No. 202510092495.3, filed on Jan. 21, 2025. The entirety of the above-mentioned patent application is hereby incorporated by reference herein and made a part of this specification.

### BACKGROUND

### Technical Field

The present disclosure generally relates to the field of lighting, and more specifically relates to a micro light-emitting diode (micro-LED) structure for improving light extraction efficiency.

### Description of Related Art

Micro-LED technology is a high-pixel-density LED flat-panel display technology that uses micrometer-scale LEDs as pixel elements, assembled on a control backplane with micrometer-scale periodicity. The core structure of the micro-LED is a PN junction diode, and the PN junction diode is composed of direct-bandgap semiconductor material. When the upper and lower electrodes apply a forward bias voltage to the micro-LED to allow current to pass through, electrons and holes recombine in the active area, and meanwhile emit monochromatic light photons.

The light emitted by LED is generated by spontaneous emission, so it is not directional, which leads to a large divergence angle. A large divergence angle will cause various problems with micro-LED displays. On the one hand, due to the large divergence angle, only a small portion of the light emitted by micro-LEDs can be utilized. This will significantly reduce the efficiency and brightness of micro-LED display systems. On the other hand, due to the large divergence angle, the light emitted by a micro-LED pixel will illuminate its adjacent pixels, thereby causing optical crosstalk, loss of sharpness, and loss of contrast between pixels. Traditional solutions for reducing the large divergence angle may not effectively handle all light emitted by the micro-LED, only efficiently utilizing the central portion of the light emitted by the micro-LED, while light emitted at more oblique angles is not utilized efficiently.

In summary, it is necessary to provide a micro-LED structure that can improve light extraction efficiency or enhance light emission effect.

### SUMMARY

One aspect of the present disclosure provides a micro-LED structure, which includes: a lower electrode layer; an omnidirectional reflector (ODR) total reflection structure disposed on the lower electrode layer; a semiconductor light-emitting mesa disposed on the ODR total reflection structure and configured to emit light; and an upper electrode layer in contact with the top of the semiconductor light-emitting mesa.

In some embodiments of the present disclosure, the thickness of the ODR total reflection structure is N times λ/4n, where N is a positive integer and λ isa wavelength of the light emitted from the semiconductor light-emitting mesa.

In some embodiments of the present disclosure, there is an inclination angle between a sidewall of the semiconductor light-emitting mesa and the bottom of the semiconductor light-emitting mesa, and the inclination angle is less than or equal to 90°.

In some embodiments of the present disclosure, the thickness of the ODR total reflection structure satisfies: H/Tan θ<(W2−W1)/2; where H is the height from the bottom of the lower electrode layer to the top of the upper electrode layer, θ is an inclination angle less than 90°, W1 is the width of the lower electrode layer, and W2 is the pixel pitch where the micro-LED structure is located.

In some embodiments of the present disclosure, the ODR total reflection structure includes: a combination of at least one conductive layer and at least one dielectric layer from top to bottom.

In some embodiments of the present disclosure, in the ODR total reflection structure, the at least one conductive layer extends downward to contact the at least one lower electrode layer.

In some embodiments of the present disclosure, the at least one conductive layer has a downward extending portion attached to a sidewall surface of the at least one dielectric layer.

In some embodiments of the present disclosure, the downward extending portion of the at least one conductive layer covers the sidewall surface of the at least one dielectric layer.

In some embodiments of the present disclosure, the material of the dielectric layer is SiO₂ or SiN; and the thickness of the at least one conductive layer ranges from 50 nm to 250 nm.

In some embodiments of the present disclosure, the thickness of the ODR total reflection structure is greater than 500 nm.

In some embodiments of the present disclosure, the thickness of the ODR total reflection structure ranges from 500 nm to 1000 nm.

In some embodiments of the present disclosure, the ODR total reflection structure comprises at least one conductive layer.

In some embodiments of the present disclosure, the conductive layer is a transparent conductive layer.

In some embodiments of the present disclosure, the material of the conductive layer is one or more of graphene, indium tin oxide (ITO), aluminum-doped zinc oxide (AZO), or fluorine-doped tin oxide (FTO).

In some embodiments of the present disclosure, the micro-LED structure further includes a passivation layer, where the passivation layer covers the side surfaces of the lower electrode layer, the ODR total reflection structure, the light-emitting mesa, and the upper electrode layer.

In some embodiments of the present disclosure, the material of the passivation layer is a dielectric material or an insulating material.

In some embodiments of the present disclosure, the material of the passivation layer is one or more of silicon oxide, silicon oxynitride, aluminum oxide, and silicon nitride.

In some embodiments of the present disclosure, the micro-LED structure further includes a pixel drive backplane, where the lower electrode layer is located on the pixel drive backplane and is electrically connected with the pixel drive backplane.

In some embodiments of the present disclosure, the pixel drive backplane adopts an integrated circuit chip.

In some embodiments of the present disclosure, the pixel drive backplane includes a substrate, at least one drive circuit, and at least one contact pad, each micro-LED structure corresponding to one of the at least one contact pad, and the at least one contact pad electrically connected with the lower electrode layer.

In some embodiments of the present disclosure, the lower electrode layer is a metal bonding composite layer.

In some embodiments of the present disclosure, the material of the lower electrode layer is an alloy of one or more of Cr, Al, Ti, Ni, Pt, Au, and Sn.

In some embodiments of the present disclosure, the inclination angle of the sidewall of the semiconductor light-emitting mesa ranges from 450 to 90°.

In some embodiments of the present disclosure, the semiconductor light-emitting mesa includes a first type epitaxial layer, a light-emitting layer, and a second type epitaxial layer, where the first type epitaxial layer is a semiconductor material having a first conductivity type and includes a plurality of semiconductor layers, and the second type epitaxial layer is a semiconductor material having a second conductivity type and includes a plurality of semiconductor layers.

In some embodiments of the present disclosure, the light-emitting layer is a quantum well light-emitting layer.

Another aspect of the present disclosure provides a micro-LED display chip including a micro-LED pixel array, and each micro-LED pixel includes the aforementioned micro-LED structures.

In embodiments of the present disclosure, by increasing the sidewall light emission area of the micro-LED, the probability of photons leaving the LED chip can be increased, so that light extraction efficiency is improved and the proportion of light emission at small angles is increased. Meanwhile, the micro-LED structure provided by the present disclosure can also achieve beam shaping and increase the proportion of light emission at small angles.

### BRIEF DESCRIPTION OF THE DRAWINGS

The present disclosure is further explained below with reference to the accompanying drawings in conjunction with specific embodiments.

FIG. 1 illustrates a cross-sectional schematic diagram of a micro-LED structure according to an embodiment of the present disclosure.

FIG. 2 illustrates a cross-sectional schematic diagram of a micro-LED structure according to an embodiment of the present disclosure.

FIG. 3 illustrates a cross-sectional schematic diagram of a micro-LED structure array according to an embodiment of the present disclosure.

FIG. 4 illustrates a schematic diagram of a curve of LEE20 varying with the thickness of the conductive layer.

FIG. 5 illustrates a schematic diagram of curves of the light intensity and light emission angle of light emitted by the micro-LED structure according to an embodiment of the present disclosure.

### DESCRIPTION OF THE EMBODIMENTS

It should be noted that various components in the accompanying drawings may be exaggerated for the purpose of illustrative illustration and are not necessarily true to scale. In the accompanying drawings, components that are identical or functionally identical are provided with the same reference number.

In the present disclosure, unless otherwise specified, the words “arranged on”, “arranged above” and “arranged over” do not exclude the existence of intermediates between the two. Furthermore, “arranged on or above” merely indicates the relative positional relationship between the two components, but under certain circumstances, such as when the product direction is reversed, it can be converted to “arranged under or below”, and vice versa.

In the present disclosure, the embodiments are merely intended to illustrate the scheme of the present disclosure and should not be construed as limiting.

In the present disclosure, the quantifiers “a” and “one” do not exclude scenarios with a plurality of elements, unless otherwise specified.

In the present disclosure, the term “connect” may refer to either the two being directly connected or the two being indirectly connected through an intermediate component.

In the present disclosure, the term “configure” refers to the setting of the shape, structure, material, and/or function of a target object to achieve a desired technical effect, where “configure” includes various alternative technical means to achieve this technical effect, these technical means become apparent under the teachings of the present disclosure.

It should also be noted herein that in embodiments of the present disclosure, merely a part of the components or assemblies may be shown for the sake of clarity and simplicity, but those ordinary skilled in the art will be able to understand that the required components or assemblies may be added as needed according to specific scenarios in light of the teachings of the present disclosure. Furthermore, features in different embodiments of the present disclosure may be combined with each other unless otherwise indicated. For example, a feature in the second embodiment may be substituted for a corresponding or functionally identical or similar feature in the first embodiment, and the obtained embodiment likewise falls within the scope of the disclosure or the scope of the record of the present application.

It should also be noted that, within the scope of the present disclosure, the terms “the same”, “equal”, “equal to”, etc. do not mean that the two numerical values are absolutely equal, but rather allow for a certain reasonable error, that is to say, the terms also cover “substantially the same”, “substantially equal” and “substantially equal to”. By analogy, in the present disclosure, the terms “perpendicular to”, “parallel to”, etc., which indicate direction, also cover the meaning of “substantially perpendicular to”, “substantially parallel to”.

In embodiments of the present disclosure, by increasing the sidewall light emission area of the micro-LED, the probability of photons leaving the LED chip can be increased, so that light extraction efficiency is improved and the proportion of light emission at small angles is increased.

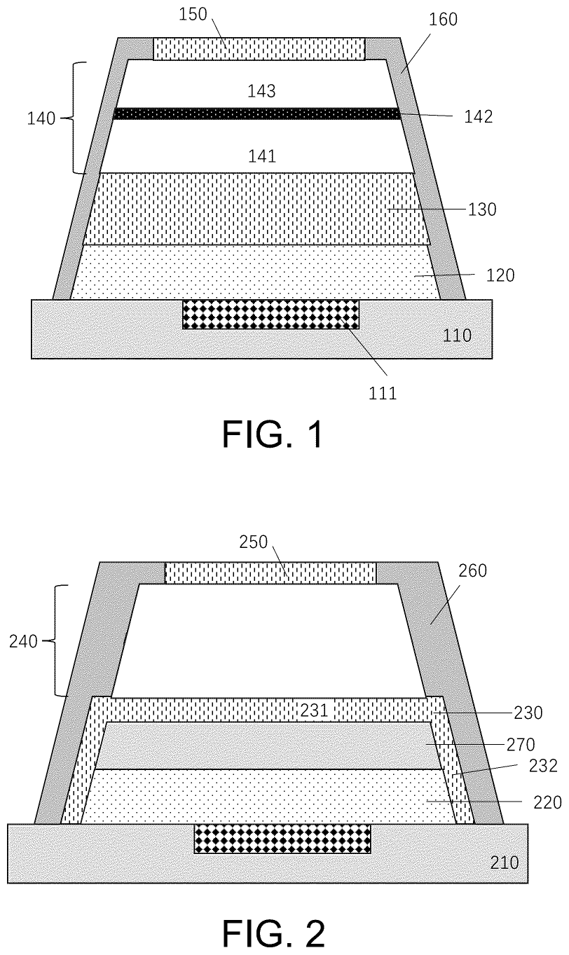

FIG. 1 illustrates a cross-sectional schematic diagram of a micro-LED structure according to an embodiment of the present disclosure. As shown in FIG. 1, the micro-LED structure includes a pixel drive backplane 110, a lower electrode layer 120, a conductive layer 130, a light-emitting mesa 140, an upper electrode layer 150, and a passivation layer 160.

For convenience, “up” is used to indicate a direction away from the pixel drive backplane 110, “down” indicates a direction towards the pixel drive backplane 110, and other directional terms such as top, bottom, above, below, directly below, and underneath, etc., are also explained accordingly.

A micro-LED is a fundamental component constituting a micro-LED pixel. Each micro-LED pixel may include one or more micro-LED structures. Multiple micro-LED pixels are arranged in an array to form a micro-LED display or a micro-LED chip. For example, each pixel in a color micro-LED chip may include multiple micro-LED structures of different colors, while each pixel in a monochrome micro-LED chip may include only micro-LED structures of one color.

In some embodiments of the present disclosure, the size of each micro-LED chip does not exceed 1 centimeter, preferably not exceeding 20 micrometers. The micro-LED structures are formed in an array in the micro-LED chip, with resolutions such as 720*480, 640*480, 1920*1080, 1280*720, 2K, or 4K. The diameter of the micro-LED structures is in the nanoscale, for example, 20 nm to 100 nm. In some embodiments, the pitch of the micro-LED array, i.e., the minimum center-to-center distance between micro-LEDs may range from approximately 2 micrometers to approximately 50 micrometers. In some embodiments, the number of pixels on a micro-LED chip may range from thousands to millions.

In some embodiments, the pixel drive backplane 110 may include an integrated circuit chip. The pixel drive backplane 110 includes a substrate, at least one drive circuit, and at least one contact pad 111. Each micro-LED corresponds to a contact pad 111, and the contact pad 111 is electrically connected with the lower electrode layer 120. Each drive circuit is a pixel driver. In some cases, the drive circuit is a thin-film transistor pixel driver or a silicon CMOS pixel driver. In one embodiment, the substrate of the pixel drive backplane 110 is a Si substrate. In another embodiment, the substrate of the pixel drive backplane 110 is a transparent substrate, such as a glass substrate. Examples of other substrates include GaAs, GaP, InP, SiC, ZnO, and sapphire substrates. The pixel drive backplane 110 is used to control the lighting and extinguishing of micro-LEDs within each pixel. In one embodiment, the material of the contact pad 111 is an alloy of one or more of the following metals: Ni, Al, Ti, Cu, Pt, and Au.

In some embodiments of the present disclosure, the pixel drive backplane may be electrically connected with each micro-LED in the micro-LED array through individual metal interconnections. In some embodiments, each micro-LED may be individually electrically controlled by the pixel drive backplane. In some embodiments, the pixel drive backplane may be electrically connected with the electrodes of the micro-LED chips through metal interconnections. In some embodiments, a dielectric layer may be formed in the gaps between the micro-LEDs. In some embodiments, the dielectric layer may also be formed in the gaps between the interconnections.

In one embodiment, the lower electrode layer 120 is a metal bonding composite layer. The light-emitting mesa 140 of the micro-LED may be bonded to the surface of the pixel drive backplane 110 through the metal bonding composite layer 120, which may be accomplished by methods such as eutectic bonding, thermal compression bonding, and transient liquid phase (TLP) bonding, etc. In one embodiment, the metal bonding composite layer 120 may be arranged on the pixel drive backplane 110. In another embodiment, the metal bonding composite layer 120 is grown on the pixel drive backplane 110. In one embodiment, the thickness of the metal bonding composite layer 120 is 0.1 micrometers to 3 micrometers. In a preferred embodiment, the thickness of the metal bonding composite layer 120 is 0.3 μm. In some embodiments, the material of the metal bonding composite layer 120 is an alloy of one or more of the following metals: Cr, Al, Ti, Ni, Pt, Au, Ag, and Sn. The metal bonding composite layer 120 may include an ohmic contact layer and a metal bonding layer. In some instances, the metal bonding composite layer 120 includes two metal layers. One of the two metal layers is deposited on a layer above the metal bonding layer within the LED. The corresponding bonding metal layer is deposited on the pixel drive backplane 110. For example, the metal bonding composite layer 120 may be Au—Au bonding, Au—Sn bonding, Au—In bonding, Ti—Ti bonding, Cu—Cu bonding, or a combination of the above. For example, if Au—Au bonding is selected, the two Au layers require a Cr layer as an adhesion layer and a Pt layer as an anti-diffusion layer, respectively. The Pt layer is located between the Au layer and the Cr layer. The Cr and Pt layers are located on the top and bottom of the two Au layers bonded together. In some embodiments, when the thicknesses of the two Au layers are substantially the same, under high pressure and high temperature, the Au on the two layers diffuses and bonds the two layers together.

In some embodiments, the metal bonding composite layer 120 may also be used as a reflector to reflect light emitted from the light-emitting mesa 140 above.

In some embodiments, the conductive layer 130 is formed on the bottom surface of the light-emitting mesa 140 to form an electrical connection between the light-emitting mesa 140 and the metal bonding composite layer 120. In some embodiments, the conductive layer 130 may be a conductive transparent layer that is transparent to light emitted from the light-emitting mesa 140 to improve conductivity and light transmittance. In some embodiments, the upper electrode layer 150 is formed on the top surface of the light-emitting mesa 140, and the upper electrode layer 150 is electrically connected with a current spreading structure or a top electrode (not shown).

In one embodiment, the conductive layer 130, the upper electrode layer 150, and their connecting components may be a combination of one or more of graphene, or indium tin oxide (ITO), or aluminum-doped zinc oxide (AZO), or fluorine-doped tin oxide (FTO), or other transparent conductive oxides (TCOs).

In some embodiments, the light-emitting mesa 140 may include a first type epitaxial layer 141, a light-emitting layer 142, and a second type epitaxial layer 143. That is, in the three-layer structure, the first type epitaxial layer 141 is closest to the pixel drive backplane 110; the light-emitting layer 142 is located above the first type epitaxial layer 141 and further away from the pixel drive backplane 110; and the second type epitaxial layer 143 is located above the light-emitting layer and furthest away from the pixel drive backplane 110. In some embodiments, the light-emitting layer 142 is formed by multiple stacked quantum well layers, particularly superlattice-stacked quantum well layers. Preferably, the superlattice-stacked quantum well layers include multiple pairs of quantum well layers stacked with quantum barrier layers. In some embodiments, the first type epitaxial layer 141 is a semiconductor material having a first conductivity type and includes a plurality of semiconductor layers. The primary base material of the first type epitaxial layer 141 may include, but not limited to, at least two or more elements of Ga, N, As, P, In, and Al. The first type epitaxial layer 141 includes, but is not limited to, a waveguide layer, a confinement layer, a transition layer, and a window layer; furthermore, an ohmic contact layer may be formed beneath the window layer. In some embodiments, the second type epitaxial layer 143 includes a semiconductor material having a second conductivity type and includes a plurality of semiconductor layers. The primary base material of the second type epitaxial layer 143 may include, but is not limited to, at least two or more elements of Ga, N, As, P, In, and Al. Furthermore, the second type epitaxial layer 143 may include, but is not limited to, a confinement layer and a waveguide layer from top to bottom; furthermore, in some embodiments, an ohmic contact layer may be formed on the confinement layer. The first type epitaxial layer 141 is electrically connected with the conductive layer 130, and the second type epitaxial layer 143 is electrically connected with the upper electrode layer 150.

In some embodiments, the first conductivity type may be N-type and the second conductivity type may be P-type; or the first conductivity type may be P-type and the second conductivity type may be N-type. The N-type semiconductor epitaxial layer includes, but is not limited to, N-type Si-doped GaN, Si-doped AlGaN, Si-doped AlGaInP, Si-doped GaAs, or Si-doped AlInP; the P-type semiconductor epitaxial layer includes, but is not limited to, Mg-doped GaN, Mg-doped AlGaN, Mg-doped InGaN, Mg-doped InAlGaN, Mg-doped AlInP, Mg-doped AlGaInP, Mg-doped GaP, or C-doped GaP. The quantum well layer includes, but is not limited to, InGaN/GaN loops and InGaP/AlGaInP loops.

In some embodiments, the electrode polarity of the conductive layer 130 is determined by the first type epitaxial layer 141, while the electrode polarity of the upper electrode layer 150 is determined by the second type epitaxial layer 143, and the electrode polarity of the conductive layer 130 is opposite to the electrode polarity of the upper electrode layer 150; the conductive layer 130 may be, for example, a P-electrode or an anode electrode, and the upper electrode layer 150 may be an electrode with polarity opposite to the conductive layer 130, such as an N-electrode or a cathode electrode, and vice versa.

In one embodiment, the light-emitting mesa 140 may be a mesa with a trapezoidal cross-section, where the bottom transverse dimension of the light-emitting mesa is greater than the top transverse dimension. There is an inclination angle between the sidewall of the semiconductor light-emitting mesa 140 and the bottom of the semiconductor light-emitting mesa, and the inclination angle is less than or equal to 90°. In one embodiment, the inclination angle of the sidewall of the light-emitting mesa ranges from 45° to 90°. In one embodiment, the bottom transverse dimension of the light-emitting mesa exceeds 2 micrometers. In one embodiment, the top transverse dimension of the light-emitting mesa does not exceed 1.5 micrometers. In one embodiment, the transverse dimension of the metal bonding composite layer is greater than the bottom transverse dimension of the light-emitting mesa.

In some embodiments, the light-emitting mesa 140 may emit red light, blue light, green light, or light of any other color.

In some embodiments, the passivation layer 160 covers the side surfaces of the metal bonding composite layer 120, the conductive layer 130, and the light-emitting mesa 140. In some embodiments of the present disclosure, the passivation layer 160 may also cover the side surface and a part of the top surface of the upper electrode layer 150, and a part of the top surface of the upper electrode layer 150 is exposed to form an electrical connection with the top electrode. In other embodiments of the present disclosure, the passivation layer 160 does not cover the top surface and side surface of the upper electrode layer 150, such that the upper electrode layers 150 of adjacent LED structures can be connected with each other as a whole to form a common cathode or anode. In some embodiments of the present disclosure, the passivation layer 160 covers the side surfaces of the metal bonding composite layer 120, the conductive layer 130, the first type epitaxial layer 141, the light-emitting layer 142, and a part of the side surface of the second type epitaxial layer 143.

In one embodiment, the material of the passivation layer is a transparent insulating material, for example, one or more of silicon dioxide, silicon oxynitride, aluminum oxide, or silicon nitride.

Under common circumstances, the thickness of the conductive layer 130 may be in the range of 50 nm to 250 nm to achieve electrical connection between the first type epitaxial layer 141 and the metal bonding composite layer 120. Light emitted from the light-emitting mesa 140 is generated by spontaneous emission and is therefore non-directional, where a part of light passes through the upper electrode layer 150 directly or after reflected by the metal bonding composite layer or other structures, and leaves the light-emitting mesa 140; a part of light passes through the passivation layer 160 directly or after reflected by the metal bonding composite layer or other structures, and leaves the light-emitting mesa 140. Light leaving the light-emitting mesa is collected by structures such as reflective structures and/or microlenses, etc., and then emitted from the front surface of the micro-LED chip or display, thereby effectively used for display or lighting. If light emitted by the light-emitting mesa 140 cannot leave the light-emitting mesa, then this part of light will not be effectively utilized.

In some embodiments of the present disclosure, the probability of light leaving the light-emitting mesa is increased by increasing the sidewall light emission area of the micro-LED structure, thereby improving the light extraction efficiency of the LED chip. Specifically, as shown in FIG. 1, the thickness of the conductive layer 130 may be greater than or equal to 500 nm. For example, the thickness of the conductive layer 130 may be in the range of 500 nm to 1000 nm. As the thickness of the conductive layer 130 increases, directly leading to an increase in the light emission area of the sidewall to increase the light extraction efficiency.

In some embodiments of the present disclosure, the thickness of the conductive layer 130 is an integer multiple of λ/4n, where λ is the working wavelength of the micro-LED and n is the refractive index of the conductive layer 130. The conductive layer 130 is combined with the lower electrode layer 120 to form an ODR structure, enhancing reflectivity to increase light extraction efficiency, where the lower electrode layer 120 serves as an ODR reflective metal, while the conductive layer 130 serves as an ODR dielectric layer.

FIG. 2 illustrates a cross-sectional schematic diagram of a micro-LED structure according to an embodiment of the present disclosure. As shown in FIG. 2, the micro-LED structure includes a pixel drive backplane 210, a lower electrode layer 220, a conductive layer 230, a light-emitting mesa 240, an upper electrode layer 250, a passivation layer 260, and a transparent dielectric layer 270. The micro-LED structure shown in FIG. 2 is similar to the micro-LED structure in FIG. 1, the primary difference of the two lies in the structure of the conductive layer 230 and the transparent dielectric layer 270 arranged between the conductive layer 230 and the lower electrode layer 220. In order to simplify the description in the following text, detailed descriptions of similar structures in FIGS. 1 and 2 will be omitted, and only the differences between the two will be described in detail.

As shown in FIG. 2, the transparent dielectric layer 270 is arranged between the conductive layer 230 and the lower electrode layer 220, which increases the light emission area of the sidewall to increase the light extraction efficiency. The material of the transparent dielectric layer 270 can be SiO₂ or SiN. In order to achieve electrical connection between the conductive layer 230 and the lower electrode layer 220, the conductive layer 230 includes a transverse portion 231 extending at the bottom of the light-emitting mesa 240 and a sidewall portion 232 extending along the sidewall towards the lower electrode layer to electrically connect with the lower electrode layer 220. The sidewall portion 232 covers the sidewalls of the transverse portion 231, the transparent dielectric layer 270, and the lower electrode layer 220. The total thickness of the conductive layer 230 and the transparent dielectric layer 270 is greater than 500 nm.

In some embodiments of the present disclosure, the lower electrode layer 220, acting as a reflective metal, combines with the conductive layer 230 and the transparent dielectric layer 270 to form an ODR structure. The conductive layer 230 and the transparent dielectric layer 270 serve as the ODR dielectric layer. The material of the lower electrode layer 220 is an alloy of one or more of the following metals: Cr, Al, Ti, Ni, Pt, Au, Ag, and Sn. The thickness of the conductive layer 230 and the thickness of the transparent dielectric layer 270 are integer multiples of λ/4n, where λ is the working wavelength of the micro-LED and n is the refractive index of the ODR dielectric layer. When the thickness of the ODR dielectric layer increases, the light emission area of the sidewall of the LED structure increases, so that the light extraction efficiency is improved. Meanwhile, due to the presence of the transparent dielectric layer 270, the thickness of the conductive layer 230 can be reduced to reduce the absorption of light by the conductive layer 230. For example, the thickness of the conductive layer 230 may be in the range of 50 to 250 nm.

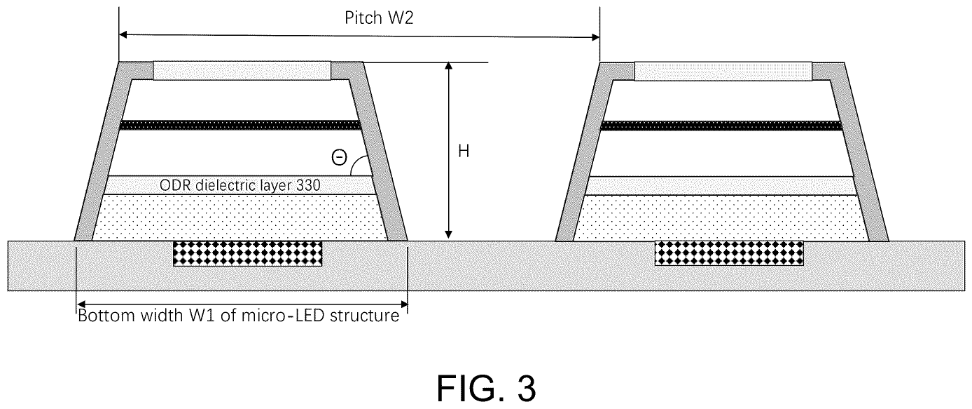

FIG. 3 illustrates a cross-sectional schematic diagram of a micro-LED structure array according to an embodiment of the present disclosure. As shown in FIG. 3, each micro-LED structure in the micro-LED structure array may be the micro-LED structure shown in FIG. 1 or FIG. 2. That is, the ODR dielectric layer 330 may be similar to the conductive layer 130 shown in FIG. 1, or the ODR dielectric layer 330 may be similar to the combination structure of the conductive layer 230 and the transparent dielectric layer 270 shown in FIG. 2. The thickness of the ODR dielectric layer 330 is an integer multiple of λ/4n, where λ is the working wavelength of the micro-LED and n is the refractive index of the ODR dielectric layer 330. When the thickness T of the ODR dielectric layer 330 increases, the light emission area of the sidewall of the LED structure increases, thereby improving the light extraction efficiency.

In one embodiment of the present disclosure, the thickness TODR of the ODR dielectric layer 330 is related to the inclination angle θ of the light-emitting mesa. When the inclination angle θ is 90°, there is no limit to the maximum thickness of the thickness TODR of the ODR dielectric layer 330. When the inclination angle θ is less than 90°, the thickness TODR of the ODR dielectric layer 330 is constrained by the bottom width W1 of the micro-LED structure, the pitch W2 of the micro-LED (i.e., the minimum center-to-center distance between micro-LEDs), and the height H of the micro-LED. The thickness TODR of the ODR dielectric layer 330 should satisfy the following formula:

$$H / Tan θ < ( W 2 - W 1 ) / 2$$

where H is the height from the bottom of the lower electrode layer to the top of the upper electrode layer, i.e., the height of the micro-LED is: H=TODR+T_{lower electrode layer}+T_{light-emitting mesa}+T_{upper electrode layer}, where T_{lower electrode layer} is the thickness of the lower electrode layer, T_{light-emitting mesa} is the thickness of the light-emitting mesa, and T_{upper electrode layer} is the thickness of the upper electrode layer.

In the embodiments of the present disclosure, by increasing the thickness of the conductive layer of the micro-LED structure, beam shaping can be achieved, and the proportion of light emitted at small angles can be increased.

Table 1 illustrates the light extraction efficiency LEE90 within a normal±90° angle, the light extraction efficiency LEE20 within a normal±20° angle, and the proportion of light emission within a normal±20° angle under different thickness of the conductive layer.

TABLE 1

| Thickness of | | | Proportion |
|---|---|---|---|
| conductive layer | LEE90 | LEE20 | of ±20° |
| 0.1 μm | 1.86% | 0.49% | 26.10% |
| 0.25 μm | 2.33% | 0.61% | 26.10% |
| 0.63 μm | 2.17% | 0.68% | 31.7% |
| 1.0 μm | 2.28% | 0.70% | 30.70% |

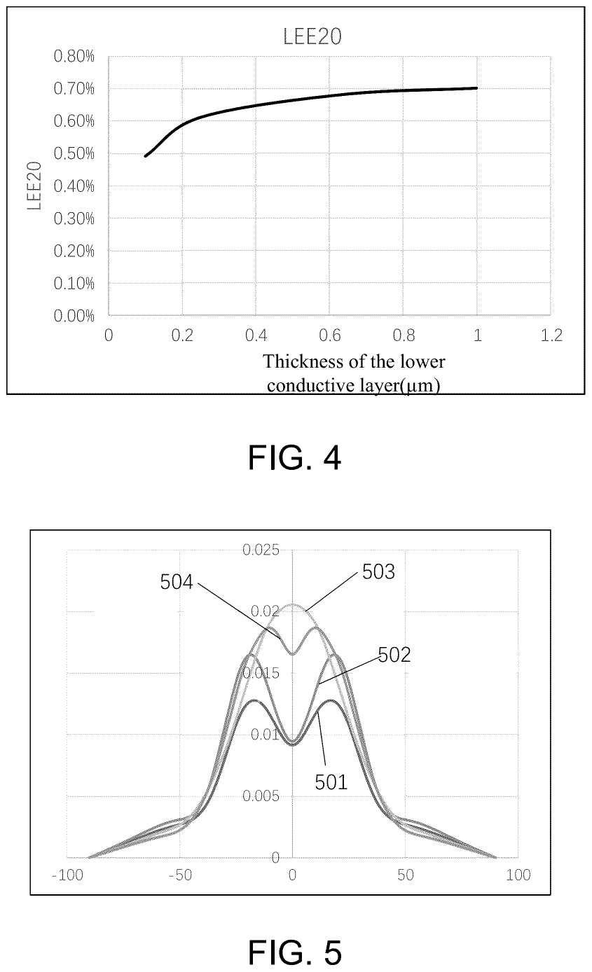

From Table 1, it can be seen that as the thickness of the conductive layer increases from 0.1 μm to 1.0 μm, LEE20 continuously increases. FIG. 4 illustrates a schematic diagram of a curve of LEE20 varying with the thickness of the conductive layer. In FIG. 4, the horizontal axis represents the thickness of the conductive layer, and the vertical axis represents LEE20.

FIG. 5 illustrates a schematic diagram of curves of the light intensity and light emission angle of light emitted by the micro-LED structure according to an embodiment of the present disclosure, where the horizontal axis represents the angle of light emission and the vertical axis represents the light intensity. In FIG. 5, curve 501 represents the variation relationship between light intensity and the light emission angle of light emitted from a micro-LED structure with a conductive layer thickness of 0.1 μm, and curve 502 represents the variation relationship between light intensity and the light emission angle of light emitted from a micro-LED structure with a conductive layer thickness of 0.25 μm, and curve 503 represents the variation relationship between light intensity and the light emission angle of light emitted from a micro-LED structure with a conductive layer thickness of 0.63 μm, and curve 504 represents the variation relationship between light intensity and the light emission angle of light emitted from a micro-LED structure with a conductive layer thickness of 1.0 μm. From Table 1 and FIG. 4, and FIG. 5, it can be seen that as the thickness of the conductive layer continuously increases, LEE20 gradually becomes larger. When the thickness of the conductive layer is 1.0 μm, the proportion of ±20° light emission increases by 15% compared to the thinnest conductive layer thickness.

In one embodiment of the present disclosure, a micro-LED display chip is also provided, including a micro-LED pixel array, and each micro-LED pixel includes the micro-LED structure described in the above embodiments.

Although some embodiments of the present disclosure have been described in the present disclosure, however, those skilled in the art will appreciate that these embodiments are merely illustrated as examples. Numerous variation schemes, alternative schemes, and improvement schemes may be conceived by those skilled in the art in light of the teachings of the present disclosure without departing from the scope of the present disclosure. The appended claims are intended to define the scope of the present disclosure and thus encompass methods and structures within the scope of these claims themselves and their equivalent variations.

What is claimed is:

1. A micro light-emitting diode (micro-LED) structure, comprising:
a lower electrode layer;
an omnidirectional reflector (ODR) total reflection structure disposed on the lower electrode layer;
a semiconductor light-emitting mesa disposed on the ODR total reflection structure, and configured to emit light; and
an upper electrode layer in contact with a top of the semiconductor light-emitting mesa.

2. The micro-LED structure according to claim 1, wherein the thickness of the ODR total reflection structure is N times λ/4n, where N is a positive integer, n is a refractive index of the ODR total reflection structure, and λ is a wavelength of the light emitted from the semiconductor light-emitting mesa.

3. The micro-LED structure according to claim 2, wherein there is an inclination angle between a sidewall of the semiconductor light-emitting mesa and a bottom of the semiconductor light-emitting mesa, and the inclination angle is less than or equal to 90°.

4. The micro-LED structure according to claim 3, wherein a thickness of the ODR total reflection structure satisfies: H/Tan θ<(W2−W1)/2, where H is a height from a bottom of the lower electrode layer to a top of the upper electrode layer, θ is an inclination angle less than 90°, W1 is a width of the lower electrode layer, and W2 is a pixel pitch where the micro-LED structure is located.

5. The micro-LED structure according to claim 1, wherein the ODR total reflection structure comprises a combination of at least one conductive layer and at least one dielectric layer from top to bottom.

6. The micro-LED structure according to claim 5, wherein in the ODR total reflection structure, the at least one conductive layer extends downward to contact the at least one lower electrode layer.

7. The micro-LED structure according to claim 6, wherein the at least one conductive layer has a downward extending portion attached to a sidewall surface of the at least one dielectric layer.

8. The micro-LED structure according to claim 7, wherein the downward extending portion of the at least one conductive layer covers the sidewall surface of the at least one dielectric layer.

9. The micro-LED structure according to claim 5, wherein a material of the at least one dielectric layer is SiO₂ or SiN; and a thickness of the at least one conductive layer ranges from 50 nm to 250 nm.

10. The micro-LED structure according to claim 1, wherein the ODR total reflection structure comprises at least one conductive layer.

11. The micro-LED structure according to claim 5, wherein the at least one conductive layer is a transparent conductive layer.

12. The micro-LED structure according to claim 11, wherein the material of the conductive layer is one or more of graphene, indium tin oxide (ITO), aluminum-doped zinc oxide (AZO), or fluorine-doped tin oxide (FTO).

13. The micro-LED structure according to claim 1, further comprising a passivation layer, wherein the passivation layer covers side surfaces of the lower electrode layer, the ODR total reflection structure, the light-emitting mesa, and the upper electrode layer.

14. The micro-LED structure according to claim 13, wherein a material of the passivation layer is a dielectric material or an insulating material.

15. The micro-LED structure according to claim 1, further comprising a pixel drive backplane, wherein the lower electrode layer is located on the pixel drive backplane and is electrically connected with the pixel drive backplane.

16. The micro-LED structure according to claim 15, wherein the pixel drive backplane adopts an integrated circuit chip.

17. The micro-LED structure according to claim 16, wherein the pixel drive backplane comprises a substrate, at least one drive circuit, and at least one contact pad, each micro-LED structure corresponding to one of the at least one contact pad, and the at least one contact pad electrically connected with the lower electrode layer.

18. The micro-LED structure according to claim 1, wherein the semiconductor light-emitting mesa comprises a first type epitaxial layer, a light-emitting layer, and a second type epitaxial layer, wherein the first type epitaxial layer is a semiconductor material having a first conductivity type and comprises a plurality of semiconductor layers, and the second type epitaxial layer is a semiconductor material having a second conductivity type and comprises a plurality of semiconductor layers.

19. The micro-LED structure according to claim 18, wherein the light-emitting layer is a quantum well light-emitting layer.

20. A micro-LED display chip, comprising a micro-LED pixel array, and each micro-LED pixel comprises the micro-LED structure according to claim 1.
